(19) United States
(12) Patent Application Publication
(10) Pub. No.: US 2015/0001696 A1
(43) Pub. Date: Jan. 1, 2015

(54) SEMICONDUCTOR DIE CARRIER STRUCTURE AND METHOD OF MANUFACTURING THE SAME

(71) Applicant: Infineon Technologies AG, Neubiberg (DE)

(72) Inventor: Chai Chee Meng, Singapore (SG)

(21) Appl. No.: 13/929,849

(22) Filed: Jun. 28, 2013

(51) Int. Cl. H01L 23/495; H01L 21/48

(52) U.S. Cl. CPC H01L 23/49503; H01L 21/4821
USPC 257/676; 174/261; 29/827

(57) ABSTRACT

Various embodiments provide a method of manufacturing a semiconductor die carrier structure. The method may include providing a die pad configured to carry a semiconductor die thereon; and bending at least one portion of the die pad, wherein the at least one bent portion extends across the die pad.

### TECHNICAL FIELD

Various embodiments relate generally to a semiconductor die carrier structure, a method of manufacturing a semiconductor die carrier structure, and a semiconductor package.

### BACKGROUND

In semiconductor packages, a die or a chip is usually mounted on a die pad which mechanically supports the die or chip thereon.

FIG. 1A shows a die pad 100, also referred to as a die paddle or a die mounting paddle, which has a planar surface for supporting the die. As shown in the side view of FIG. 1B, the die 102 is mounted on the planar surface of the die pad 100. The die 102 may be attached to the surface of the die pad 100 by means of a die attach material, e.g. through adhesive. The die 102 and the die pad 100 may be encapsulated using encapsulation material to form a semiconductor package.

In IC (integrated circuit) packaging, the die 102 and the die pad 100 of FIG. 1A and FIG. 1B may encounter die delamination problems and/or die crack problems, e.g. due to warpage of the die pad under heat or force.

Existing approaches to address the die delamination and/or die crack problems are unique to specific package design, and there is no standardized method suitable for any package design.

### SUMMARY

Various embodiments provide a method of manufacturing a semiconductor die carrier structure. The method may include providing a die pad configured to carry a semiconductor die thereon; and bending at least one portion of the die pad, wherein the at least one bent portion extends across the die pad.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a die pad, and FIG. 1B shows a side view of a die pad and a die mounted thereon.

FIG. 2 shows a flowchart illustrating a method of manufacturing a semiconductor die carrier structure according to various embodiments;

FIG. 3 shows a flowchart illustrating a method of manufacturing a semiconductor die carrier structure according to various embodiments;

FIG. 4A shows an isometric (ISO) view of a semiconductor die carrier structure according to various embodiments;

FIG. 4B shows a cross-sectional view of a semiconductor die carrier structure according to various embodiments;

FIGS. 5A to 5D show an isometric (ISO) view, a cross-sectional view, a top view, and a side view of a semiconductor die carrier structure according to various embodiments, respectively;

FIGS. 6A to 6D show an isometric (ISO) view, a cross-sectional view, a top view, and a side view of a semiconductor die carrier structure according to various embodiments, respectively;

FIGS. 7A to 7D show cross-sectional views of semiconductor die carrier structures according to various embodiments;

FIGS. 8A to 8D show an isometric (ISO) view, a cross-sectional view, a top view, and a side view of a semiconductor die carrier structure according to various embodiments, respectively; and

FIG. 9 shows a semiconductor package according to various embodiments.

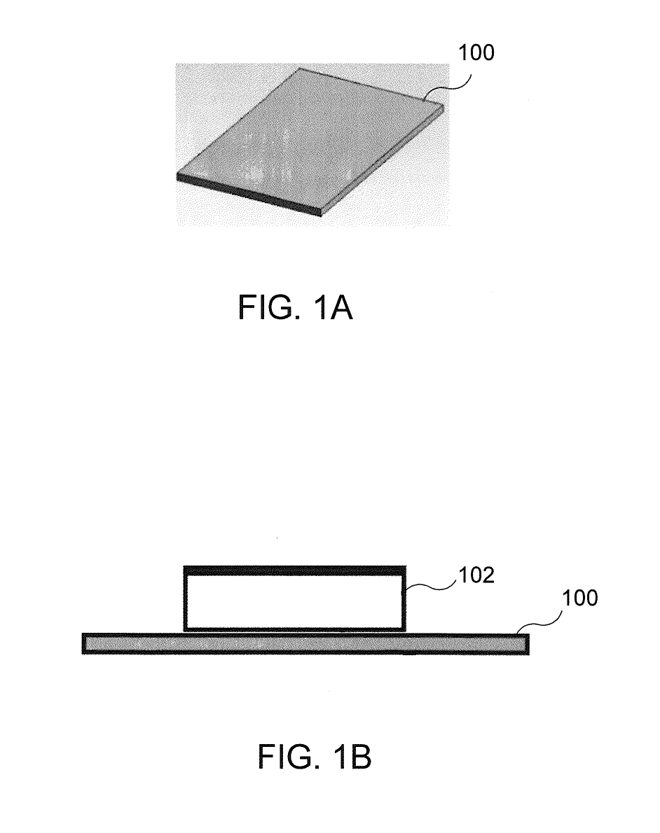

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

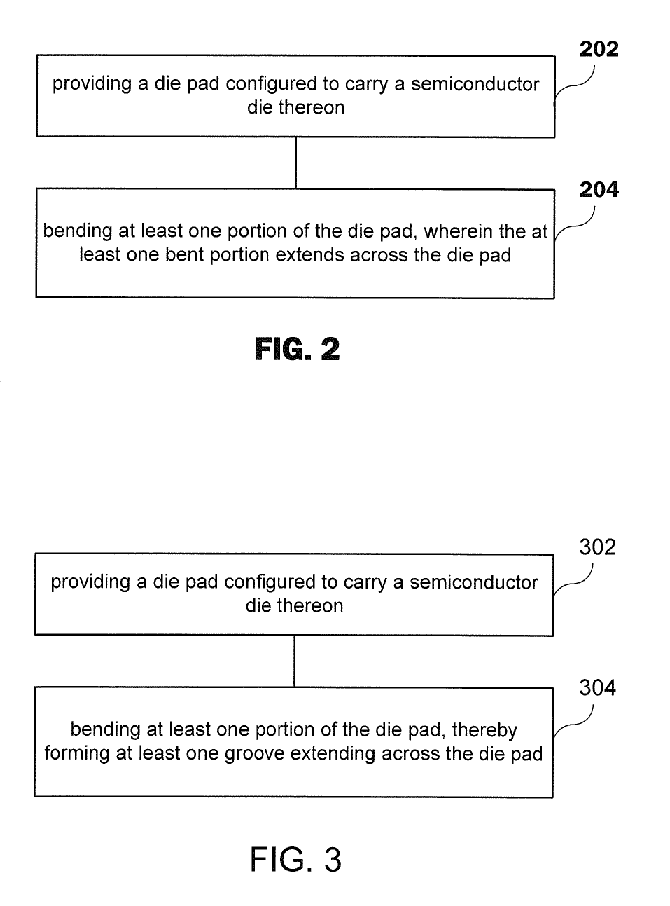

FIG. 2 shows a flowchart illustrating a method of manufacturing a semiconductor die carrier structure according to various embodiments.

At 202, a die pad configured to carry a semiconductor die thereon may be provided.

At 204, at least one portion of the die pad may be bent, wherein the at least one bent portion extends across the die pad.

In various embodiments, the at least one bent portion extending across the die pad may refer to at least one bent portion extending across the main surface of the die pad, e.g. the surface on which the die is mounted. By way of example, the at least one bent portion may extend from a first side to a second side of the die pad. The first side and the second side may be adjacent to each other, e.g. as two adjacent edges of a rectangular or square die pad. In various embodiments, the die pad may have any arbitrarily desired shape. The first side and the second side may also be opposite to each other, e.g. as two opposite edges of a rectangular or square die pad.

In various embodiments, the at least one bent portion may extend from a first edge of the die pad to a second edge of the die pad, the second edge being opposite to the first edge.

According to various embodiments, the method may include bending at least one edge area of the die pad to form at least one bent edge.

In various embodiments, the at least one bent edge may be located on a first surface of the die pad on which the semiconductor die is carried, or located on a second surface of the die pad opposite to the first surface.

In various embodiments, the method may include bending at least one edge area of the die pad towards a direction substantially perpendicular to a surface of the die pad. In various embodiments, the method may include forming at least one bent edge bent in the direction substantially perpendicular to the surface of the die pad.

According to various embodiments, the method may include bending at least one portion of the die pad at a distance from the perimeter of the die pad, thereby forming the at least one bent portion at a distance from the perimeter of the die pad.

In various embodiments, the at least one bent portion formed at a distance from the perimeter of the die pad may include a groove. In various embodiments, the at least one bent portion formed at a distance from the perimeter of the die pad may include at least one of a V-groove, a U-groove, or a zigzag groove.

In various embodiments, the at least one portion of the die pad may be bent via stamping (also referred to as pressing), by pressing or forcing the die pad against a tool using a punch. The tool may have a predetermined shape, e.g., a concave channel in V-shape, U-shape or zigzag shape, corresponding to the profile of the bent portion. Accordingly, the bent portion formed against the tool may be or may include a groove formed on the die pad, such as a V-groove, a U-groove, or a zigzag groove. In various embodiments, the at least one portion of the die pad may be bent via stamping, by clamping an edge of the die pad and folding/bending the die pad around a bend profile. Accordingly, the bent portion may be or may include a bent edge.

FIG. 3 shows a flowchart illustrating a method of manufacturing a semiconductor die carrier structure according to various embodiments.

At 302, a die pad configured to carry a semiconductor die thereon is provided.

At 304, at least one portion of the die pad is bent, thereby forming at least one groove extending across the die pad.

In various embodiments, the at least one groove extending across the die pad may refer to at least one groove extending across the main surface of the die pad, e.g. extending from a first side to a second side of the die pad. The first side and the second side may be adjacent to each other, e.g. as two adjacent edges of a rectangular or square die pad. The first side and the second side may also be opposite to each other, e.g. as two opposite edges of a rectangular or square die pad. In various embodiments, the at least one groove may extend from a first edge of the die pad to a second edge of the die pad, the second edge being opposite to the first edge.

According to various embodiments, the method may include bending at least one portion of the die pad at a distance from the perimeter of the die pad, thereby forming the at least one groove at a distance from the perimeter of the die pad (e.g. away from the edge area of the die pad). According to various embodiments, the method may include bending at least one portion of the die pad at the edge area of the die pad, thereby forming the at least one groove at the edge area of the die pad.

The at least one groove may include at least one of a V-groove, a U-groove, or a zigzag groove.

The at least one portion of the die pad may be bent via stamping, by pressing or forcing the die pad against a tool using a punch. The tool may have a predetermined form, e.g., a concave channel in V-shape, U-shape or zigzag shape, corresponding to the profile of the bent portion. Accordingly, the bent portion formed against the tool may be or may include a groove formed on the die pad, such as a V-groove, a U-groove, or a zigzag groove. In various embodiments, the at least one portion of the die pad may be bent via stamping, by clamping an edge of the die pad and folding/bending the die pad around a bend profile, e.g. a bend profile of V-shape, U-shape or zigzag shape, so as to form the at least one groove.

Various embodiments of the method for manufacturing a semiconductor die carrier structure described above are analogously valid for the semiconductor die carrier structure described in the following.

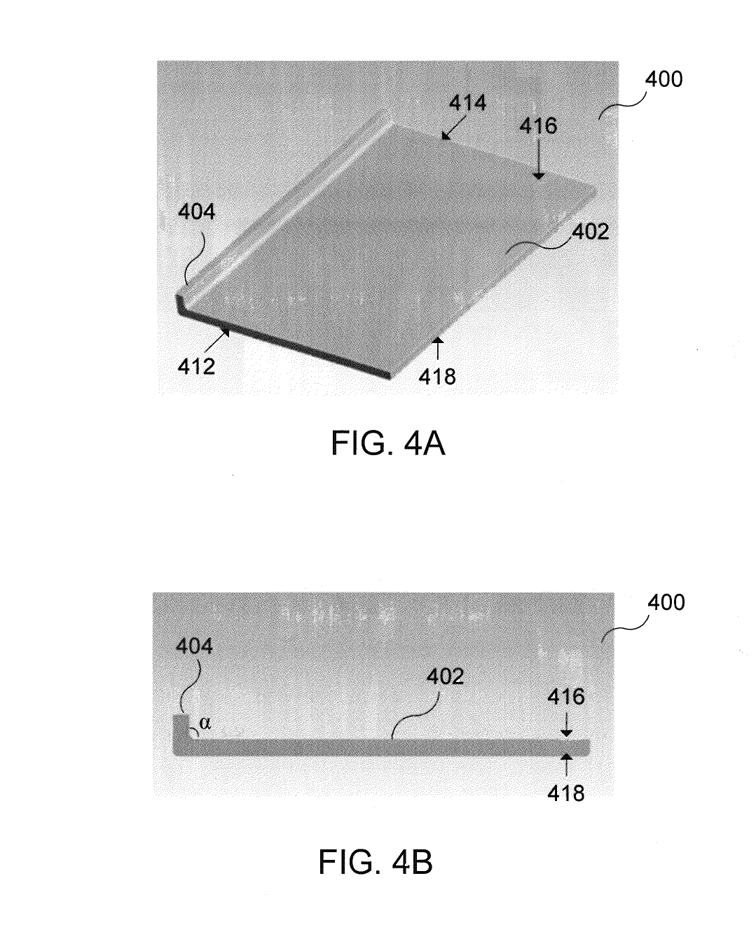

FIG. 4A shows an isometric (ISO) view of a semiconductor die carrier structure 400 according to various embodiments, and FIG. 4B shows a cross-sectional view of a semiconductor die carrier structure 400 according to various embodiments.

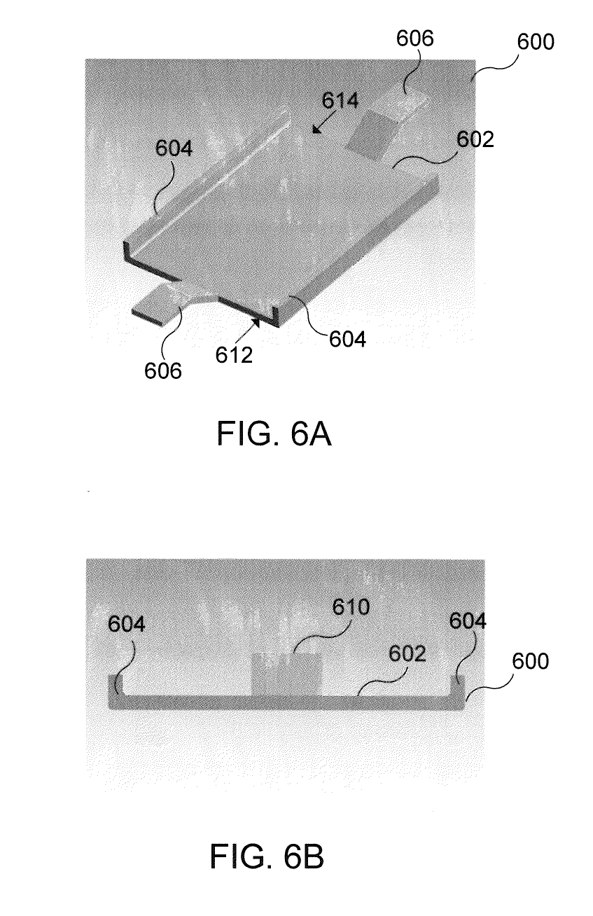

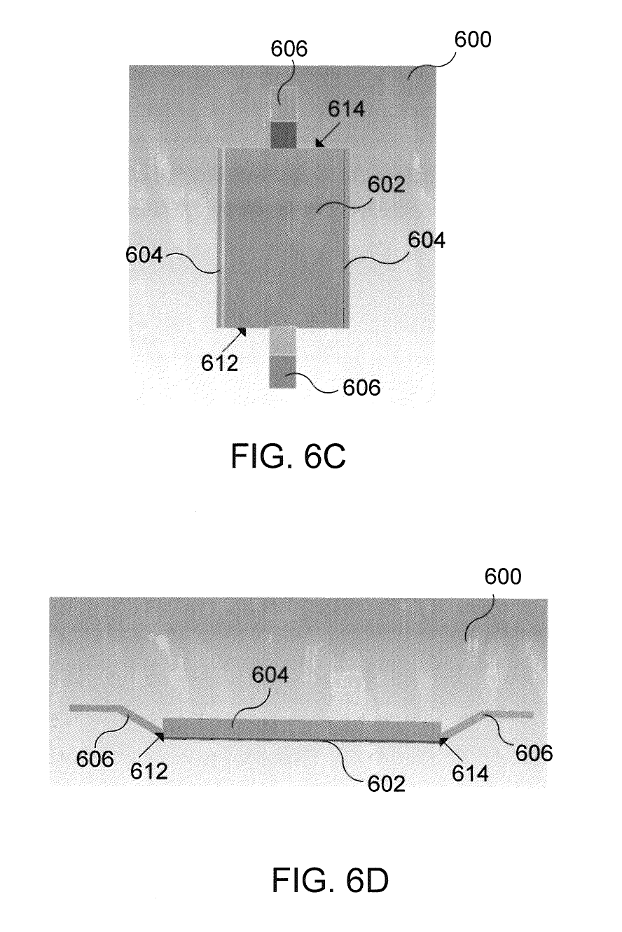

As shown in FIG. 4A and FIG. 4B, a semiconductor die carrier structure 400 may include a die pad 402 configured to carry a semiconductor die (not shown) thereon, wherein the die pad 402 includes at least one bent portion 404 extending across the die pad. In various embodiments of FIGS. 4A and 4B, the die pad 402 includes one bent portion 404, but the die pad 402 may include more than one bent portions as will be shown in FIGS. 6A to 6D below.

The bent portion 404 may extend across the main surface of the die pad 402, e.g. the planar surface of the die pad 402 on which the die is mounted. In various embodiments shown in FIG. 4A, the bent portion 404 may extend from a first edge 412 of the die pad 402 to a second edge 414 of the die pad 402, the second edge 414 being opposite to the first edge 412. It is understood that the bent portion 404 may also extend from the first edge 412 of the die pad 402 to a third edge of the die pad 402, wherein the third edge is adjacent to the first edge.

In various embodiments shown in FIGS. 4A and 4B, the bent portion 404 may be a bent edge of the die pad 402.

In various embodiments as shown in FIGS. 4A and 4B, the bent edge 404 may be located on a first surface 416 of the die pad 402 on which the semiconductor die is carried. In various embodiments as will be described below, the bent edge may also be located on a second surface 418 of the die pad 402 opposite to the first surface 416.

In various embodiments, the bent edge 404 of the die pad 402 may be bent in a direction substantially perpendicular to a surface of the die pad, e.g. the first surface 416 and the second surface 418 of the die pad 402, so as to form a substantially 90° bent edge 404. In various embodiments, the angle α between the bent edge 404 and the first surface 416 of the die pad 402 may be in a range from about 45° to about 160°, e.g. 60°, 80°, 100°, 120°, 135°, 150°, etc.

The bent edge 404 adding on the flat die pad 402 provides a die pad stiffener, which may change the die pad structure and increase die pad rigidity to support the semiconductor die from bending and warpage. With the at least one bent portion, the die pad may be more rigid to withstand package warpage and may reduce bending force acting on the die. This may reduce die crack and die delamination problem encountered in IC packaging.

According to various embodiments, the semiconductor die carrier structure 400 may include a leadframe, wherein the leadframe may include the die pad 402 (also referred to as die paddle or die mounting paddle) described above to mechanically support the semiconductor die and may include lead fingers (not shown) for connecting the semiconductor die to external circuitry. The leadframe and the die pad 402 may be made of a metal or a metal alloy, e.g. including a material selected from a group consisting of: copper (Cu), iron nickel (FeNi), steel, and the like.

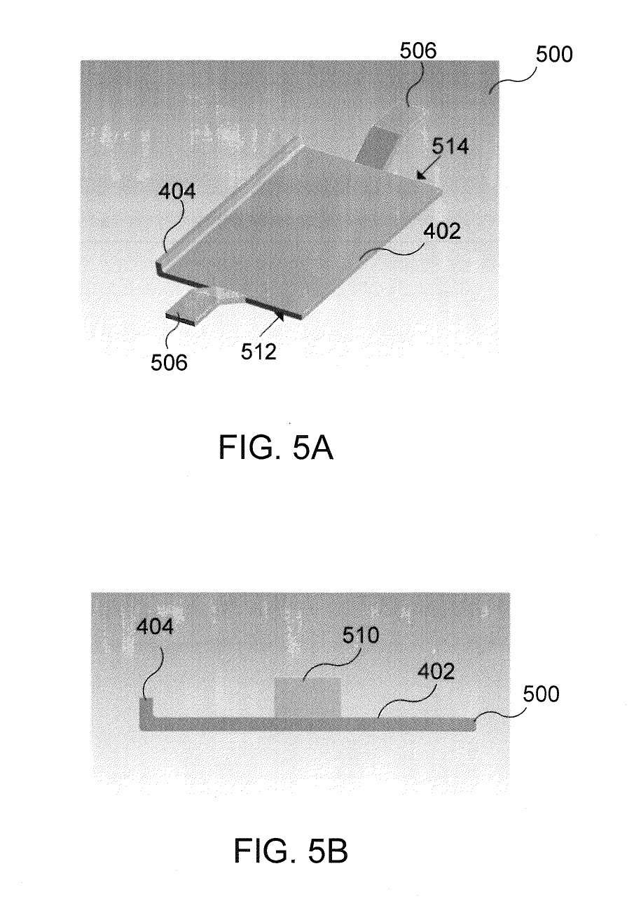

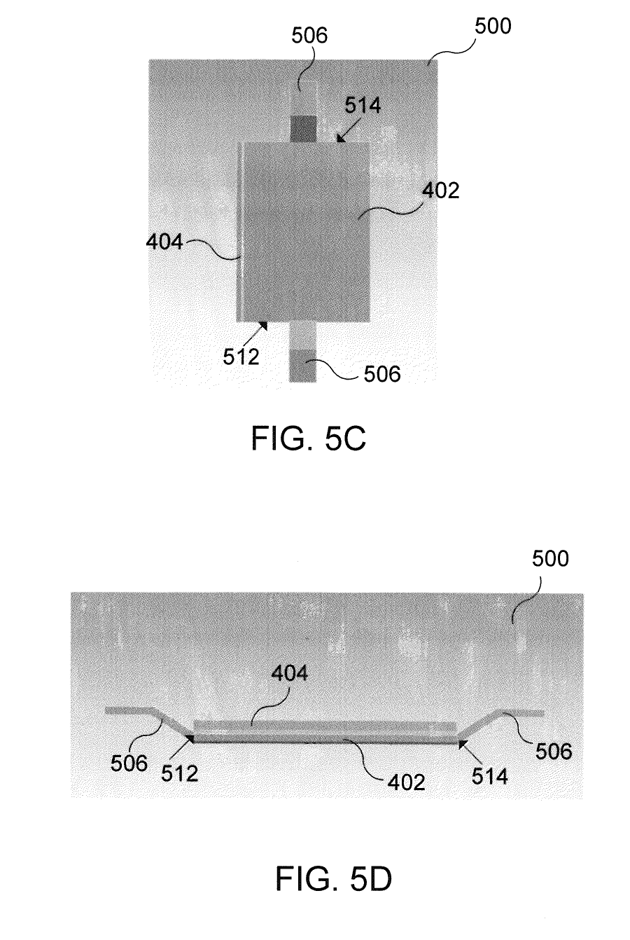

FIGS. 5A to 5D show an isometric (ISO) view, a cross-sectional view, a top view, and a side view of a semiconductor die carrier structure 500 according to various embodiments, respectively.

Similar to the semiconductor die carrier structure 400 of FIGS. 4A and 4B, the semiconductor die carrier structure 500 as shown in FIGS. 5A to 5D includes the die pad 402 configured to carry a semiconductor die 510 (shown in FIG. 5B) thereon, wherein the die pad 402 includes at least one bent portion 404 extending across the die pad. In various embodiments of FIGS. 5A to 5D, one bent portion 404, e.g. one bent edge, is shown but the die pad 402 may include more than one bent portions.

Various embodiments described with regard to the semiconductor die carrier structure 400 of FIGS. 4A and 4B above are also valid for the semiconductor die carrier structure 500.

In various embodiments, the semiconductor die carrier structure 500 may also include one or more supporters 506 attached to one or more edges 512, 514 of the die pad 402 and extending from the edges 512, 514 to the external of the die pad 402. The bent portion 404 and the supporters 506 may be located at different edges of the die pad 402.

In various embodiments in FIGS. 5A, 5C and 5D, two supporters (which may also be referred to as support structures, e.g. in the form of tongues) 506 are shown extending from two opposing edges 512, 514 to the external of the die pad 402, respectively. The bent edge 404 may be formed at an edge of the die pad 402 different from the two opposing edges 512, 514 of the die pad 402 where the two supporters 506 are located. In other words, the bent portion 404 and the supporters 506 are located at different edges of the die pad 402.

In various embodiments, four supporters (not shown) may be provided at four edges of the die pad and the bent portion 404 may be formed at a distance from the perimeter of the die pad, i.e. at the central area enclosed by the perimeter of the die pad.

FIGS. 6A to 6D show an isometric (ISO) view, a cross-sectional view, a top view, and a side view of a semiconductor die carrier structure 600 according to various embodiments, respectively.

The semiconductor die carrier structure 600 is similar to the semiconductor die carrier structure 400, 500 of FIGS. 4A, 4B, 5A-5D above, and various embodiments described with regard to the semiconductor die carrier structure 400, 500 analogously apply to the semiconductor die carrier structure 600.

The semiconductor die carrier structure 600 may include a die pad 602 configured to carry a semiconductor die 610 (shown in FIG. 6B) thereon, wherein the die pad 602 includes at least one bent portion 604 extending across the die pad.

In various embodiments of FIGS. 6A to 6D, two bent portions 604, e.g. two bent edges, are formed extending from a first edge 612 of the die pad 602 to a second edge 614 of the die pad 602, the second edge 614 being opposite to the first edge 612.

A supporter 606 may be provided at each of the first edge 612 and the second edge 614 of the die pad 602, and may extend to the external of the die pad 602.

Although the embodiments of FIGS. 6A to 6D show two bent edges 604 extending from the first edge 612 to the second edge 614 of the die pad 602, it is understood that more than two bent edges may be formed in the die pad 602, e.g. the first edge 612 and/or the second edge 614 may be bent to form further bent edges, e.g. the die pad 602 may include three or four bent edges. The supporters 606 may be provided at a different location of the die pad 602, e.g. at the backside (e.g. the bottom surface) of the die pad 602.

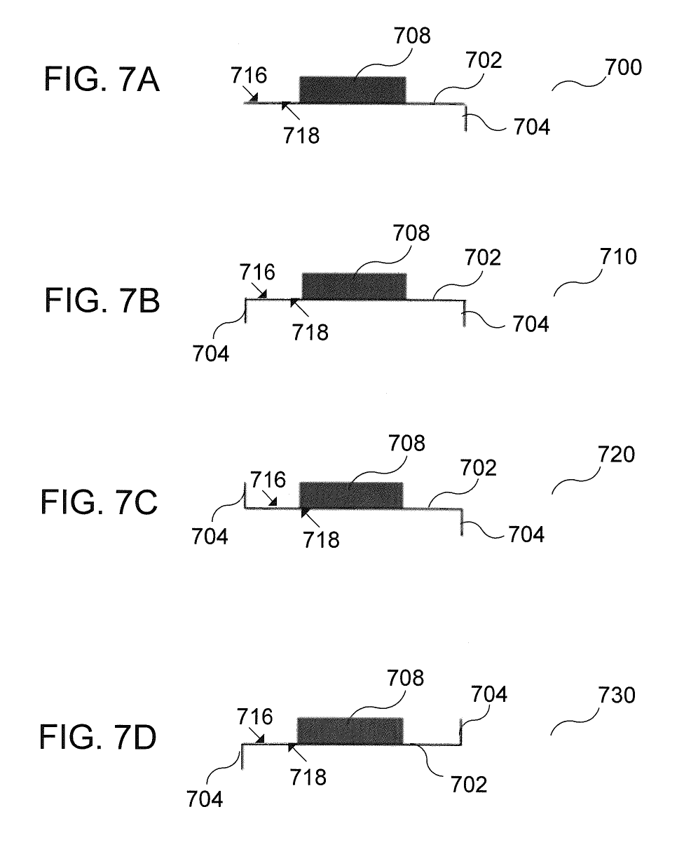

In the cross-sectional view shown in FIGS. 4B and 5B, the bent edge 404 may be located on the first surface 416 of the die pad 402 on which the semiconductor die is carried. Similarly, in the cross-sectional view of FIG. 6B, the bent edge 604 is located on the surface of the die pad 602 on which the semiconductor die 610 is carried. It is understood that in various embodiments at least one bent portion may also be located on another surface of the die pad opposite to the surface on which the semiconductor is carried. FIGS. 7A to 7D show cross-sectional views of semiconductor die carrier structures according to various embodiments.

In the semiconductor die carrier structures 700, 710 of FIGS. 7A and 7B, the die pad 702 may include one or two bent portions 704 located on a second surface 718 of the die pad 702, wherein the second surface 718 is opposite to a first surface 716 of the die pad 702 on which a semiconductor die 708 is mounted.

In the semiconductor die carrier structures 720, 730 of FIGS. 7C and 7D, the die pad 702 may include a bent portion 704 located on the first surface 716 of the die pad 702 on which the semiconductor die 708 is mounted, and may also include a bent portion 704 located on the second surface 718 of the die pad 702 opposite to the first surface 716. The bent portion 704 located on the first surface 716 of the die pad 702 may be formed by bending the edge of the die pad upwardly, and the bent portion 704 located on the second surface 718 of the die pad 702 may be formed by bending the edge of the die pad downwardly.

The cross-sectional views in FIGS. 4B, 5B, 6B, 7A to 7D show the bent portions/edges bent in a direction substantially perpendicular to a surface of the die pad, e.g. the main surface of the die pad on which the semiconductor die is mounted, so as to form substantially 90° bent edges. It is understood that in various embodiments, the bent edges may be bent to an extent such that the angle between the bent edge and the surface of the die pad on which the semiconductor die is mounted may be in a range from about 45° to about 160°, e.g. 60°, 80°, 100°, 120°, 135°, 150°, etc.

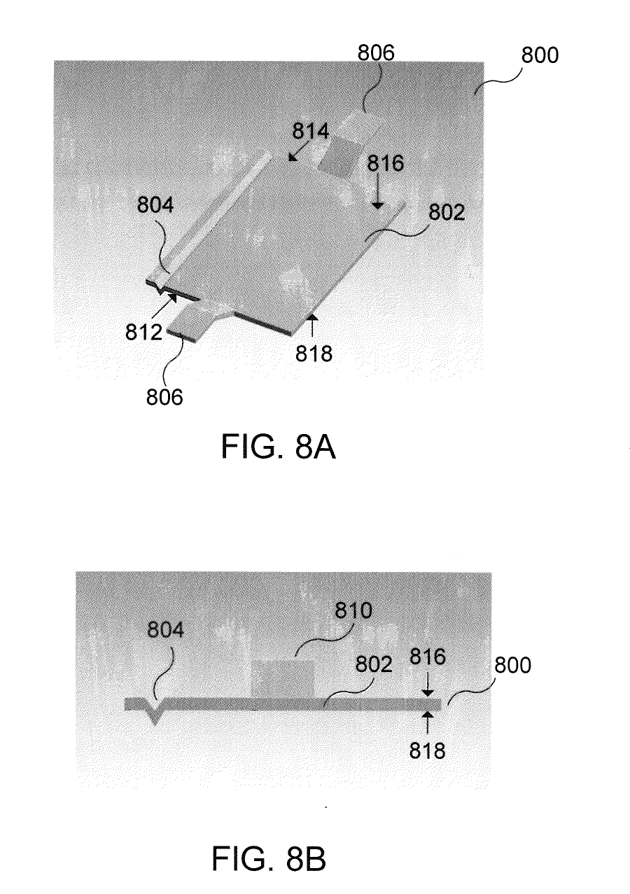

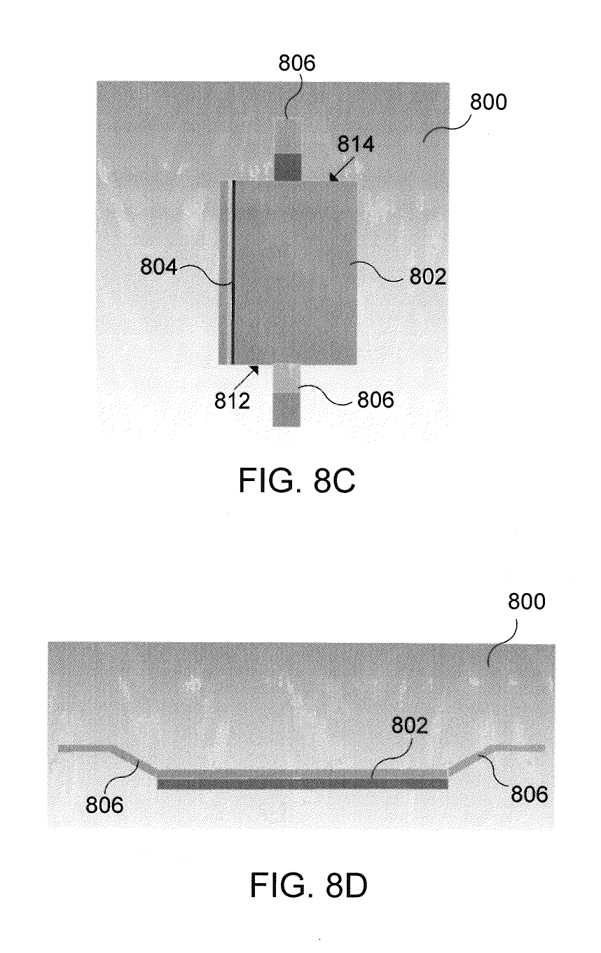

The various embodiments above show a semiconductor die carrier structure in which the die pad includes one or more bent edges at the edge area of the die pad. In various embodiments, the die pad may include one or more bent portions at a distance from the perimeter of the die pad, in other words, away from at least one edge area of the die pad, as illustrated in FIGS. 8A to 8D below.

FIGS. 8A to 8D show an isometric (ISO) view, a cross-sectional view, a top view, and a side view of a semiconductor die carrier structure 800 according to various embodiments, respectively.

As shown in FIGS. 8A to 8D, the semiconductor die carrier structure 800 may include a die pad 802 configured to carry a semiconductor die 810 (shown in FIG. 8B) thereon, wherein the die pad 802 includes at least one bent portion 804 extending across the die pad 802. In various embodiments of FIGS. 8A to 8D, the die pad 802 includes one bent portion 804, but the die pad 802 may include more than one bent portions extending across the die pad 802.

In various embodiments, the bent portion 804 may extend across the surface of the die pad 802, e.g. across a first surface 816 of the die pad 802 on which the die 810 is mounted and a second surface 818 of the die pad 802 opposite to the first surface 816, e.g. extending from a first side to a second side of the die pad 802. The first side and the second side may be adjacent to each other, e.g. as two adjacent edges of a rectangular or square die pad. The first side and the second side may also be opposite to each other, e.g. as two opposite edges of a rectangular or square die pad.

In various embodiments shown in FIG. 8A and FIG. 8C, the bent portion 804 may extend from a first edge 812 of the die pad 802 to a second edge 814 of the die pad 802, the second edge 814 being opposite to the first edge 812. It is understood that the bent portion 804 may also extend from the first edge 812 of the die pad 802 to a third edge of the die pad 802, wherein the third edge is adjacent to the first edge, such that the bent portion 804 may be formed along an oblique line crossing the surface 816 of the die pad 802.

According to various embodiments, the bent portion 804 of the die pad 802 may include at least one bent portion at a distance from the perimeter of the die pad 802, e.g. as shown in FIG. 8B. In various embodiments, the bent portion 804 at a distance from the perimeter of the die pad 802 may refer to a bent portion having a longitudinal body at a distance away from the edge of the die pad 802. The two ends of the longitudinal body of the bent portion 804 may intersect or contact with the edge of the die pad 802, e.g. the first edge 812 and the second edge 814 of the die pad 802. In various embodiments (not shown in FIGS. 8A to 8D), the bent portion 804 may also be formed at the edge area of the die pad 802, e.g. the longitudinal body of the bent portion may be at the edge of the die pad 802.

In various embodiments, the at least one bent portion 804 may include a groove 804. In various embodiments, the at least one bent portion 804 may include at least one of a V-groove, a U-groove, or a zigzag groove. In the embodiments of FIGS. 8A to 8D, the die pad 802 including a V-groove 802 is shown. It is understood that more than one grooves may be included in the die pad 802.

In various embodiments, the semiconductor die carrier structure 800 may also include one or more supporters 806 attached to the edges 812, 814 of the die pad 802 and extending from the edges 812, 814 to the external of the die pad 802.

Various embodiments above describes various semiconductor die carrier structures 400, 500, 600, 700, 710, 720, 730, 800 including a die pad, wherein the die pad includes at least one bent portion extending across the die pad. The die pad having at least one bent portion according to various embodiments helps to change the die pad structure and increase die paddle rigidity to prevent the die from bending and warpage. The at least one bent portion provides a die pad/paddle stiffener to strengthen die pad/paddle from excessive warpage and to reduce bending force acting on the semiconductor die mounted thereon. Therefore, various embodiments improve reliability performance of the semiconductor die carrier structures and the semiconductor package formed thereon.

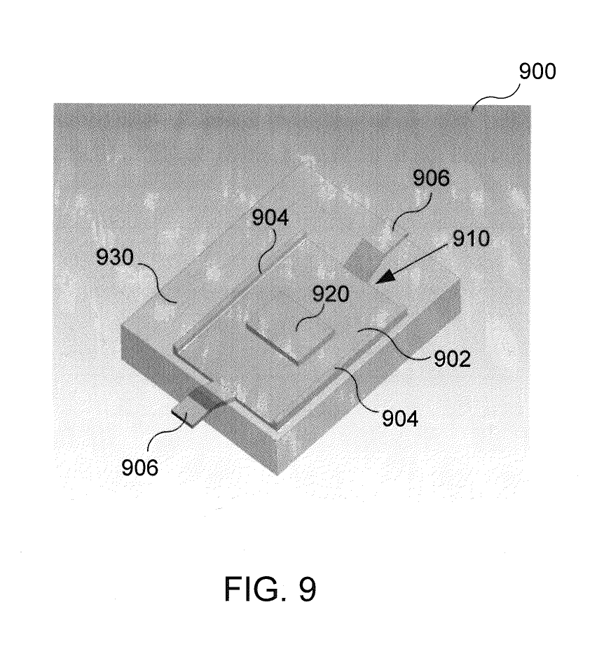

FIG. 9 shows a semiconductor package 900 according to various embodiments.

The semiconductor package 900 may include a semiconductor die carrier structure 910 including a die pad 902 configured to carry a semiconductor die 920 thereon, wherein the die pad 902 includes at least one bent portion 904 extending across the die pad 902. The semiconductor package 900 may further include the semiconductor die 920 arranged over the semiconductor die carrier structure 910; and encapsulation material 930 formed at least partially over the semiconductor die carrier structure 910 and the semiconductor die 920.

The semiconductor die carrier structure 910 included in the semiconductor package may be the semiconductor die carrier structure 400, 500, 600, 700, 710, 720, 730, 800 described in various embodiments above.

In the embodiments shown in FIG. 9, the die pad 902 may include two bent portions 904 formed as bent edges 904 located at two opposing edges of the die pad 902. It is understood that the die pad 902 may include various number of bent portions, in the form of bent edges or grooves located at the edge area of the die pad or at a distance from the perimeter of the die pad as described in various embodiments above.

The semiconductor die carrier structure 910 may include one or more supporters 906 attached to the edges of the die pad 902 and extending outwardly from the die pad 902.

In various embodiments, the semiconductor die 920 may include one or more electronic component or an integrated circuit (also referred to as a chip). By way of example, a power chip may be arranged on the semiconductor die carrier structure 910. The power chip may include a power diode chip and/or a power transistor chip (e.g. a power MOSFET (metal oxide semiconductor field effect transistor), a JFET (junction field effect transistor), an IGBT (insulated gate bipolar transistor), a power bipolar transistor, or the like).

In various embodiments, the semiconductor die 920 may be arranged over the semiconductor die carrier structure 910, e.g. over the die pad 902, through adhesive. The adhesive may be an insulating adhesive, in which case the semiconductor die carrier structure 910 may be used as a cooling structure. The adhesive may be an electrically conductive adhesive, in which case the semiconductor die carrier structure 910 may be used to electrically connect the terminal of the semiconductor die 920 to the semiconductor die carrier structure 910. The semiconductor die 920 may be arranged over the semiconductor die carrier structure 910, e.g. over the die pad 902, in a flipped manner through soldering.

In various embodiments, the encapsulating material 930 may include mold compound, such as filled epoxy, e.g. epoxy filled with SiO. The encapsulation material 930 may include a laminate, such as polymer material with glass fibers.

Various embodiments provide a method of manufacturing a semiconductor die carrier structure. The method may include providing a die pad configured to carry a semiconductor die thereon; and bending at least one portion of the die pad, wherein the at least one bent portion extends across the die pad.

In various embodiments, the at least one bent portion extending across the die pad may refer to at least one bent portion extending across the main surface of the die pad, e.g. extending from a first side to a second side of the die pad. The first side and the second side may be adjacent to each other, e.g. as two adjacent edges of a rectangular or square die pad. The first side and the second side may also be opposite to each other, e.g. as two opposite edges of a rectangular or square die pad.

In various embodiments, the at least one bent portion may extend from a first edge of the die pad to a second edge of the die pad, the second edge being opposite to the first edge.

According to various embodiments, the method may include bending at least one edge area of the die pad to form at least one bent edge.

In various embodiments, the at least one bent edge may be located on a first surface of the die pad on which the semiconductor die is carried, or located on a second surface of the die pad opposite to the first surface.

In various embodiments, the method may include bending at least one edge area of the die pad towards a direction substantially perpendicular to a surface of the die pad. In various embodiments, the method may include forming at least one bent edge bent in the direction substantially perpendicular to the surface of the die pad.

According to various embodiments, the method may include bending at least one portion of the die pad at a distance from the perimeter of the die pad, thereby forming the at least one bent portion at a distance from the perimeter of the die pad.

In various embodiments, the at least one bent portion formed at a distance from the perimeter of the die pad may include a groove. The at least one bent portion formed at a distance from the perimeter of the die pad may include at least one of a V-groove, a U-groove, or a zigzag groove.

In various embodiments, bending at least one portion of the die pad may be carried out via stamping (also referred to as pressing). The at least one portion of the die pad may be bent via stamping, by pressing or forcing the die pad against a tool using a punch. The tool may have having a predetermined form, e.g., a concave channel in V-shape, U-shape or zigzag shape, corresponding to the profile of the bent portion. Accordingly, the bent portion formed against the tool may be or may include a groove formed on the die pad, such as a V-groove, a U-groove, or a zigzag groove. In various embodiments, the at least one portion of the die pad may be bent via stamping, by clamping an edge of the die pad and folding/bending the die pad around a bend profile. Accordingly, the bent portion may be or may include a bent edge.

Various embodiments further provides a method of manufacturing a semiconductor die carrier structure. The method may include providing a die pad configured to carry a semiconductor die thereon; and bending at least one portion of the die pad, thereby forming at least one groove extending across the die pad.

In various embodiments, the at least one groove extending across the die pad may refer to at least one groove extending across the main surface of the die pad, e.g. extending from a first side to a second side of the die pad. The first side and the second side may be adjacent to each other, e.g. as two adjacent edges of a rectangular or square die pad. The first side and the second side may also be opposite to each other, e.g. as two opposite edges of a rectangular or square die pad. In various embodiments, the at least one groove may extend from a first edge of the die pad to a second edge of the die pad, the second edge being opposite to the first edge.

According to various embodiments, the method may include bending at least one portion of the die pad at a distance from the perimeter of the die pad, thereby forming the at least one groove at a distance from the perimeter of the die pad (e.g. away from the edge area of the die pad). The method may include bending at least one portion of the die pad at the edge area of the die pad, thereby forming the at least one groove at the edge area of the die pad.

In various embodiments, the at least one groove may include at least one of a V-groove, a U-groove, or a zigzag groove.

In various embodiments, bending at least one portion of the die pad may be carried out via stamping (also referred to as pressing). The at least one portion of the die pad may be bent via stamping, by pressing or forcing the die pad against a tool using a punch. The tool may have having a predetermined form, e.g., a concave channel in V-shape, U-shape or zigzag shape, corresponding to the profile of the bent portion. Accordingly, the bent portion formed against the tool may be or may include a groove formed on the die pad, such as a V-groove, a U-groove, or a zigzag groove. In various embodiments, the at least one portion of the die pad may be bent via stamping, by clamping an edge of the die pad and folding/bending the die pad around a bend profile, e.g. a bend profile of V-shape, U-shape or zigzag shape, so as to form the at least one groove.

Various embodiments of the method for manufacturing a semiconductor die carrier structure described above are analogously valid for the semiconductor die carrier structure described in the following.

Various embodiments further provide a semiconductor die carrier structure. The semiconductor die carrier structure may include a die pad configured to carry a semiconductor die thereon, wherein the die pad includes at least one bent portion extending across the die pad.

In various embodiments, the at least one bent portion extending across the die pad may refer to at least one bent portion extending across the main surface of the die pad, e.g. extending from a first side to a second side of the die pad. The first side and the second side may be adjacent to each other, e.g. as two adjacent edges of a rectangular or square die pad. The first side and the second side may also be opposite to each other, e.g. as two opposite edges of a rectangular or square die pad.

In various embodiments, the at least one bent portion may extend from a first edge of the die pad to a second edge of the die pad, the second edge being opposite to the first edge.

According to various embodiments, the at least one bent portion may include at least one bent edge of the die pad.

In various embodiments, the at least one bent edge may be located on a first surface of the die pad on which the semiconductor die is carried, or located on a second surface of the die pad opposite to the first surface.

In various embodiments, the at least one bent edge of the die pad may be bent in a direction substantially perpendicular to a surface of the die pad.

According to various embodiments, the at least one bent portion of the die pad may include at least one bent portion at a distance from the perimeter of the die pad.

In various embodiments, the at least one bent portion at a distance from the perimeter of the die pad may include a groove. In various embodiments, the at least one bent portion at a distance from the perimeter of the die pad may include at least one of a V-groove, a U-groove, or a zigzag groove.

According to various embodiments, the semiconductor die carrier structure may include a leadframe, wherein the leadframe may include the die pad (also referred to as die paddle or die mounting paddle) for mechanically support the semiconductor die and may include lead fingers for connecting the semiconductor die to external circuitry. The leadframe and the die pad therein may be made of a metal or a metal alloy, e.g. including a material selected from a group consisting of: copper (Cu), iron nickel (FeNi), steel, and the like.

Various embodiments further provide a semiconductor die carrier structure. The semiconductor die carrier structure may include a die pad configured to carry a semiconductor die thereon, wherein the die pad includes at least one groove extending across the die pad.

In various embodiments, the at least one groove extending across the die pad may refer to at least one groove extending across the main surface of the die pad, e.g. extending from a first side to a second side of the die pad. The first side and the second side may be adjacent to each other, e.g. as two adjacent edges of a rectangular or square die pad. The first side and the second side may also be opposite to each other, e.g. as two opposite edges of a rectangular or square die pad. In various embodiments, the at least one groove may extend from a first edge of the die pad to a second edge of the die pad, the second edge being opposite to the first edge.

According to various embodiments, the at least one groove of the die pad may be formed at a distance from the perimeter of the die pad (e.g. away from the edge area of the die pad), or may be formed at the edge area of the die pad.

In various embodiments, the at least one groove may include at least one of a V-groove, a U-groove, or a zigzag groove.

According to various embodiments, the semiconductor die carrier structure may include a leadframe, wherein the leadframe may include the die pad (also referred to as die paddle or die mounting paddle) for mechanically support the semiconductor die and may include lead fingers for connecting the semiconductor die to external circuitry. The leadframe and the die pad therein may be made of a metal or a metal alloy, e.g. including a material selected from a group consisting of: copper (Cu), iron nickel (FeNi), steel, and the like.

Various embodiments further provide a semiconductor package. The semiconductor package may include a semiconductor die carrier structure including a die pad configured to carry a semiconductor die thereon, wherein the die pad includes at least one bent portion extending across the die pad. The semiconductor package may further include the semiconductor die arranged over the semiconductor die carrier structure; and encapsulation material formed at least partially over the semiconductor die carrier structure and the semiconductor die.

The semiconductor die carrier structure included in the semiconductor package may be the semiconductor die carrier structure described in various embodiments above.

In various embodiments, the semiconductor die may include one or more electronic component or an integrated circuit (also referred to as a chip). By way of example, a power chip may be arranged on the semiconductor die carrier structure. The power chip may include a power diode chip and/or a power transistor chip (e.g. a power MOSFET (metal oxide semiconductor field effect transistor), a JFET (junction field effect transistor), an IGBT (insulated gate bipolar transistor), a power bipolar transistor, or the like).

In various embodiments, the semiconductor die may be arranged over the semiconductor die carrier structure, e.g. over the die pad, through adhesive. In various embodiments, the adhesive may be an insulating adhesive, in which case the semiconductor die carrier structure may be used as a cooling structure. In various embodiments, the adhesive may be an electrically conductive adhesive, in which case the semiconductor die carrier structure may be used to electrically connect the terminal of the semiconductor die to the semiconductor die carrier structure. In various embodiments, the semiconductor die may be arranged over the semiconductor die carrier structure, e.g. over the die pad, in a flipped manner through soldering.

In various embodiments, the encapsulating material may include mold compound, such as filled epoxy, e.g. epoxy filled with SiO. In various embodiments, the encapsulation material may include a laminate, such as polymer material with glass fibers.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method of manufacturing a semiconductor die carrier structure, the method comprising:
providing a die pad configured to carry a semiconductor die thereon;
bending at least one portion of the die pad, wherein the at least one bent portion extends across the die pad.

2. The method of claim 1, wherein
the at least one bent portion extends from a first edge of the die pad to a second edge of the die pad, the second edge being opposite to the first edge.

3. The method of claim 1, further comprising
bending at least one edge area of the die pad to form at least one bent edge.

4. The method of claim 3, wherein
the at least one bent edge is located on a first surface of the die pad on which the semiconductor die is carried, or located on a second surface of the die pad opposite to the first surface.

5. The method of claim 1, further comprising
bending at least one edge area of the die pad towards a direction substantially perpendicular to a surface of the die pad.

6. The method of claim 5, further comprising
forming at least one bent edge bent in the direction substantially perpendicular to the surface of the die pad.

7. The method of claim 1, further comprising
bending at least one portion of the die pad at a distance from the perimeter of the die pad, thereby forming the at least one bent portion at a distance from the perimeter of the die pad.

8. The method of claim 7, wherein
the at least one bent portion formed at a distance from the perimeter of the die pad comprises a groove.

9. The method of claim 7, wherein
the at least one bent portion formed at a distance from the perimeter of the die pad comprises at least one of a V-groove, a U-groove, or a zigzag groove.

10. The method of claim 1, further comprising
bending at least one portion of the die pad via stamping.

11. A semiconductor die carrier structure, comprising:
a die pad configured to carry a semiconductor die thereon,
wherein the die pad comprises at least one bent portion extending across the die pad.

12. The semiconductor die carrier structure of claim 11, wherein
the at least one bent portion extends from a first edge of the die pad to a second edge of the die pad, the second edge being opposite to the first edge.

13. The semiconductor die carrier structure of claim 11, wherein
the at least one bent portion comprises at least one bent edge of the die pad.

14. The semiconductor die carrier structure of claim 13, wherein
the at least one bent edge is located on a first surface of the die pad on which the semiconductor die is carried, or located on a second surface of the die pad opposite to the first surface.

15. The semiconductor die carrier structure of claim 13, wherein
the at least one bent edge is bent in a direction substantially perpendicular to a surface of the die pad.

16. The semiconductor die carrier structure of claim 11, wherein
the at least one bent portion comprises at least one bent portion at a distance from the perimeter of the die pad.

17. The semiconductor die carrier structure of claim 11, wherein
the at least one bent portion at a distance from the perimeter of the die pad comprises a groove.

18. The semiconductor die carrier structure of claim 11, wherein
the at least one bent portion at a distance from the perimeter of the die pad comprises at least one of a V-groove, a U-groove, or a zigzag groove.

19. The semiconductor die carrier structure of claim 11, wherein
the semiconductor die carrier structure comprises a leadframe.

20. A semiconductor package, comprising:
a semiconductor die carrier structure, comprising:
a die pad configured to carry a semiconductor die thereon, wherein the die pad comprises at least one bent portion extending across the die pad;
the semiconductor die arranged over the semiconductor die carrier structure; and
encapsulation material formed at least partially over the semiconductor die carrier structure and the semiconductor die.
